(19) United States
(12) Patent Application Publication
(10) Pub. No.: US 2026/0127348 A1
(43) Pub. Date: May 7, 2026

(54) OPTIMIZATION OF MULTI-DOMAIN CLOCK GATING CIRCUITS

(71) Applicant: International Business Machines Corporation, Armonk, NY (US)

(72) Inventors: William Richard Migatz, Wappingers Falls, NY (US); Cindy S. Washburn, Poughquag, NY (US)

(21) Appl. No.: 18/939,697

(22) Filed: Nov. 7, 2024

(51) Int. Cl. G06F 30/34; G06F 30/337

(52) U.S. Cl. CPC G06F 30/34; G06F 30/337

(57) ABSTRACT

Embodiments of the disclosure include a method for optimizing multi-domain clock gating circuits. The method involves associating intermediate local clock buffers to latches, the latches being associated with clock domains. The method involves clustering the intermediate local clock buffers according to connectable groups between the intermediate local clock buffers, the connectable groups supporting the clock domains. The method involves converting the connectable groups of the intermediate local clock buffers into a plurality of local clock buffers of an integrated circuit, where the plurality of local clock buffers are converted from the connectable groups according to a number of the clock domains supported by the plurality of local clock buffers.

### BACKGROUND

Power consumption in integrated circuits has become an increasingly important consideration in modern electronic device design. As the demand for more powerful and energy-efficient devices continues to grow, designers may face challenges in accurately modeling and analyzing power consumption, particularly in complex circuits with multiple clock domains.

Traditional clock gating techniques may be used to reduce power consumption by selectively disabling portions of a circuit when they are not in use. However, these techniques may have limitations when applied to circuits with numerous small clock gated domains. In such cases, using standard Local Clock Buffers (LCBs) for each domain may result in a large number of underloaded LCBs, potentially leading to inefficient power usage.

To address this issue, multi-domain clock gating circuits, such as Micro Clock Gating LCBs (MCG LCBs), may be implemented. These circuits may allow a single LCB to drive multiple domains, with additional enable signals for separate control of each domain. While this approach may offer potential power savings, it may also introduce new challenges in analysis and circuit design.

### SUMMARY

Embodiments of the disclosure include a method for performing circuit design optimization for an integrated circuit. The method includes associating intermediate local clock buffers to latches, the latches being associated with clock domains. Also, the method includes clustering the intermediate local clock buffers according to connectable groups between the intermediate local clock buffers, the connectable groups supporting the clock domains. Further, the method includes converting the connectable groups of the intermediate local clock buffers into a plurality of local clock buffers of an integrated circuit, wherein the plurality of local clock buffers are converted from the connectable groups according to a number of the clock domains supported by the plurality of local clock buffers.

Embodiments of the disclosure include a system having a memory having computer readable instructions and a processing device for executing the computer readable instructions, the computer readable instructions controlling the processing device to perform operations. The operations include associating intermediate local clock buffers to latches, the latches being associated with clock domains. Also, the operations include clustering the intermediate local clock buffers according to connectable groups between the intermediate local clock buffers, the connectable groups supporting the clock domains. Further, the operations include converting the connectable groups of the intermediate local clock buffers into a plurality of local clock buffers of an integrated circuit, wherein the plurality of local clock buffers are converted from the connectable groups according to a number of the clock domains supported by the plurality of local clock buffers.

Embodiments of the disclosure also include a computer program product for circuit design optimization. The computer program product has a set of one or more computer-readable storage media and program instructions, collectively stored in the set of one or more storage media, for causing a processor set to perform computer operations. The operations include associating intermediate local clock buffers to latches, the latches being associated with clock domains. Also, the operations include clustering the intermediate local clock buffers according to connectable groups between the intermediate local clock buffers, the connectable groups supporting the clock domains. Further, the operations include converting the connectable groups of the intermediate local clock buffers into a plurality of local clock buffers of an integrated circuit, wherein the plurality of local clock buffers are converted from the connectable groups according to a number of the clock domains supported by the plurality of local clock buffers.

Embodiments of the disclosure include a method for optimizing an integrated circuit. The method includes associating intermediate local clock buffers to latches, the latches being associated with clock domains. Also, the method includes creating a graph of the intermediate local clock buffers in which the intermediate local clock buffers are vertices and the vertices are connected by edges, the edges representing the intermediate local clock buffers that are mergeable. The method includes clustering the intermediate local clock buffers in the graph according to cliques, the cliques supporting clock domains. Further, the method includes converting the cliques of the intermediate local clock buffers into a plurality of local clock buffers of the integrated circuit, wherein the plurality of local clock buffers are converted from the cliques according to a number of the clock domains supported by the plurality of local clock buffers.

Embodiments of the disclosure include a system having a memory having computer readable instructions and a processing device for executing the computer readable instructions, the computer readable instructions controlling the processing device to perform operations. The operations include associating intermediate local clock buffers to latches, the latches being associated with clock domains. Also, the operations include creating a graph of the intermediate local clock buffers in which the intermediate local clock buffers are vertices and the vertices are connected by edges, the edges representing the intermediate local clock buffers that are mergeable. The operations include finding cliques in the graph, the cliques including the intermediate local clock buffers and supporting clock domains. Further, the operations include converting the cliques of the intermediate local clock buffers into a plurality of local clock buffers of the integrated circuit, wherein the plurality of local clock buffers are converted from the cliques according to a number of the clock domains supported by the plurality of local clock buffers.

The above features and advantages, and other features and advantages, of the disclosure are readily apparent from the following detailed description when taken in connection with the accompanying drawings.

### BRIEF DESCRIPTION OF THE DRAWINGS

FIG. 1 illustrates a computing environment for executing methods related to circuit design optimization in accordance with an exemplary embodiment.

FIG. 2 illustrates a flow diagram of a method for optimizing use of different types of local clock buffers for clock domains in accordance with an exemplary embodiment.

FIG. 3 illustrates a flow diagram of a computer-implemented method for performing circuit design optimization utilizing different types of local clock buffers in accordance with an exemplary embodiment.

FIGS. 4A and 4B illustrate block diagrams of multi-domain clock gating circuits with global and micro enables in accordance with an exemplary embodiment.

FIG. 4C illustrates a block diagram of single clock gating circuit in accordance with an exemplary embodiment.

FIG. 5 illustrates a flow diagram of a computer-implemented method for performing circuit design optimization utilizing different types of local clock buffers in accordance with an exemplary embodiment.

FIG. 6 illustrates an example graph of intermediate local clock buffers with different clock domains in accordance with an exemplary embodiment.

FIG. 7 illustrates an example of identifying cliques for fully connected subgraphs in accordance with an exemplary embodiment.

FIG. 8 illustrates as a set of cliques that fully cover the graph in accordance with an exemplary embodiment.

FIG. 9 is a schematic of a multi-domain clock gating circuit with multiple enable signals and corresponding output clocks in accordance with an exemplary embodiment.

FIG. 10 illustrates a flowchart of a computer-implemented method for circuit design optimization of attaching latches to different types of local clock buffers according to clock domains in order to form an integrated circuit in accordance with an exemplary embodiment.

FIG. 11 illustrates a flowchart of a computer-implemented method for circuit design optimization of attaching latches to different types of local clock buffers according to clock domains in order to form an integrated circuit in accordance with an exemplary embodiment.

FIG. 12 is a block diagram of a system to perform circuit design in accordance with an exemplary embodiment.

FIG. 13 is a flow diagram of a method of fabricating an integrated circuit in accordance with an exemplary embodiment.

The above features and advantages, and other features and advantages, of the disclosure are readily apparent from the following detailed description when taken in connection with the accompanying drawings.

### DETAILED DESCRIPTION

According to one or more embodiments, a computer-implemented method includes associating intermediate local clock buffers to latches, the latches being associated with clock domains. The method includes clustering the intermediate local clock buffers according to connectable/mergeable groups between the intermediate local clock buffers, the connectable groups supporting the clock domains. Also, the method includes converting the connectable groups of the intermediate local clock buffers into a plurality of local clock buffers of an integrated circuit, wherein the plurality of local clock buffers are converted from the connectable groups according to a number of the clock domains supported by the plurality of local clock buffers. Technical effects and solutions include enhancing power efficiency by associating intermediate local clock buffers to latches within specific clock domains, allowing for optimized clustering and conversion into local clock buffers that support multiple domains, thereby reducing power consumption and improving circuit performance. This provides an efficient circuit of different types of local clock buffers connected to latches of different clock gating domains, thereby allowing the combination of clock domains for gating (e.g., power off) latches for minimizing power consumption in an integrated circuit.

In addition to one or more of the features described above or below, additional features disclose the intermediate local clock buffers include a predefined portion of drive power of the plurality of local clock buffers. Technical effects and solutions provide a scalable approach to power management by ensuring that intermediate local clock buffers utilize a predefined portion of drive power, which allows for more precise control over power distribution and consumption across the integrated circuit.

In addition to one or more of the features described above or below, additional features disclose a connectable group in the connectable groups includes the intermediate local clock buffers that are convertible to a local clock buffer. Technical effects and solutions facilitate efficient conversion of intermediate local clock buffers by defining connectable groups that can be transformed into local clock buffers, thus streamlining the design process and enhancing the adaptability of the circuit to various power requirements.

In addition to one or more of the features described above or below, additional features disclose the connectable groups are cliques in which each clique includes up to a predefined number of the intermediate local clock buffers. Technical effects and solutions improve computational efficiency by organizing connectable groups into cliques, which simplifies the process of identifying optimal configurations for power management.

In addition to one or more of the features described above or below, additional features disclose executing a weighted set covering algorithm to find a set of the connectable groups to account for all of the intermediate local clock buffers. Technical effects and solutions utilize advanced algorithms to identify the most cost-effective set of connectable groups, ensuring comprehensive coverage of all intermediate local clock buffers and optimizing the overall power management strategy.

In addition to one or more of the features described above or below, additional features disclose that each connectable group in the set of the connectable groups is converted to one of the plurality of local clock buffers. Technical effects and solutions ensure that each connectable group is effectively converted into a local clock buffer, thereby making the best use of the different types of local clock buffers according to the number of functional outputs that they support.

In addition to one or more of the features described above or below, additional features disclose a first type of the plurality of local clock buffers supports a first number of the clock domains. Technical effects and solutions support diverse power management needs by allowing for different types of local clock buffers, each capable of supporting a specific number of clock domains, thus providing flexibility in circuit design and optimization.

In addition to one or more of the features described above or below, additional features disclose a second type of the plurality of local clock buffers supports a second number of the clock domains, the second number being less than the first number. Technical effects and solutions offer a hierarchical approach to power management by introducing a second type of local clock buffer that supports fewer clock domains than the first type, enabling more granular control over power distribution.

In addition to one or more of the features described above or below, additional features disclose a second type of the plurality of local clock buffers supports a second number of the clock domains, the second number being less than the first number, and a third type of the plurality of local clock buffers supports a third number of the clock domains, the third number being less than the second number. Technical effects and solutions extend the hierarchical power management strategy by incorporating a third type of local clock buffer that supports even fewer clock domains, allowing for precise tuning of power consumption and enhancing the overall energy efficiency of the integrated circuit.

According to one or more embodiments, a system includes a memory comprising computer readable instructions and a processing device for executing the computer readable instructions, the computer readable instructions controlling the processing device to perform operations. The operations include associating intermediate local clock buffers to latches, the latches being associated with clock domains. The operations include clustering the intermediate local clock buffers according to connectable groups between the intermediate local clock buffers, the connectable groups supporting the clock domains. Also, the operations include converting the connectable groups of the intermediate local clock buffers into a plurality of local clock buffers of an integrated circuit, wherein the plurality of local clock buffers are converted from the connectable groups according to a number of the clock domains supported by the plurality of local clock buffers. Technical effects and solutions include enhancing power efficiency by associating intermediate local clock buffers to latches within specific clock domains, allowing for optimized clustering and conversion into local clock buffers that support multiple domains, thereby reducing power consumption and improving circuit performance. This provides an efficient circuit of different types of local clock buffers connected to latches of different clock domains, thereby allowing the combination of clock domains for gating (e.g., power off) latches for minimizing power consumption in an integrated circuit.

In addition to one or more of the features described above or below, additional features disclose the intermediate local clock buffers include a predefined portion of drive power of the plurality of local clock buffers. Technical effects and solutions provide a scalable approach to power management by ensuring that intermediate local clock buffers utilize a predefined portion of drive power, which allows for more precise control over power distribution and consumption across the integrated circuit.

In addition to one or more of the features described above or below, additional features disclose a connectable group in the connectable groups includes the intermediate local clock buffers that are convertible to a local clock buffer. Technical effects and solutions facilitate efficient conversion of intermediate local clock buffers by defining connectable groups that can be transformed into local clock buffers, thus streamlining the design process and enhancing the adaptability of the circuit to various power requirements.

In addition to one or more of the features described above or below, additional features disclose the connectable groups are cliques in which each clique includes up to a predefined number of the intermediate local clock buffers. Technical effects and solutions improve computational efficiency by organizing connectable groups into cliques, which simplifies the process of identifying optimal configurations for power management.

In addition to one or more of the features described above or below, additional features disclose executing a weighted set covering algorithm to find a set of the connectable groups (e.g., cliques) to account for all of the intermediate local clock buffers. Technical effects and solutions utilize advanced algorithms to identify the most cost-effective set of connectable groups, ensuring comprehensive coverage of all intermediate local clock buffers and optimizing the overall power management strategy.

In addition to one or more of the features described above or below, additional features disclose that each connectable group (e.g., clique) in the set of the connectable groups (e.g., cliques) is converted to one of the plurality of local clock buffers. Technical effects and solutions ensure that each connectable group is effectively converted into a local clock buffer, thereby making the best use of the different types of local clock buffers according to the number of functional outputs that they support.

In addition to one or more of the features described above or below, additional features disclose a first type of the plurality of local clock buffers supports a first number of the clock domains. Technical effects and solutions support diverse power management needs by allowing for different types of local clock buffers, each capable of supporting a specific number of clock domains, thus providing flexibility in circuit design and optimization.

In addition to one or more of the features described above or below, additional features disclose a second type of the plurality of local clock buffers supports a second number of the clock domains, the second number being less than the first number. Technical effects and solutions offer a hierarchical approach to power management by introducing a second type of local clock buffer that supports fewer clock domains than the first type, enabling more granular control over power distribution.

In addition to one or more of the features described above or below, additional features disclose a second type of the plurality of local clock buffers supports a second number of the clock domains, the second number being less than the first number, and a third type of the plurality of local clock buffers supports a third number of the clock domains, the third number being less than the second number. Technical effects and solutions extend the hierarchical power management strategy by incorporating a third type of local clock buffer that supports even fewer clock domains, allowing for precise tuning of power consumption and enhancing the overall energy efficiency of the integrated circuit.

According to one or more embodiments, a computer program product includes a set of one or more computer-readable storage media, and program instructions, collectively stored in the set of one or more storage media, for causing a processor set to perform the following computer operations. The computer operations include associating intermediate local clock buffers to latches, the latches being associated with clock domains. Also, the computer operations include clustering the intermediate local clock buffers according to connectable groups between the intermediate local clock buffers, the connectable groups supporting the clock domains. Further, computer operations include converting the connectable groups of the intermediate local clock buffers into a plurality of local clock buffers of an integrated circuit, wherein the plurality of local clock buffers are converted from the connectable groups according to a number of the clock domains supported by the plurality of local clock buffers. Technical effects and solutions include enhancing power efficiency by associating intermediate local clock buffers to latches within specific clock domains, allowing for optimized clustering and conversion into local clock buffers that support multiple domains, thereby reducing power consumption and improving circuit performance. This provides an efficient circuit of different types of local clock buffers connected to latches of different clock domains, thereby allowing the combination of clock domains for gating (e.g., power off) latches for minimizing power consumption in an integrated circuit.

In addition to one or more of the features described above or below, additional features disclose the intermediate local clock buffers include a predefined portion of drive power of the plurality of local clock buffers. Technical effects and solutions utilize a predefined portion of the drive power for intermediate local clock buffers to convert the associated clock domain to a functional output of a local clock buffer.

In addition to one or more of the features described above or below, additional features disclose a connectable group in the connectable groups includes the intermediate local clock buffers that are convertible to a local clock buffer. Technical effects and solutions facilitate efficient conversion of intermediate local clock buffers by defining connectable groups that can be transformed into local clock buffers, thus streamlining the design process and enhancing the adaptability of the circuit to various power requirements.

In addition to one or more of the features described above or below, additional features disclose the connectable groups are cliques in which each clique includes up to a predefined number of the intermediate local clock buffers. Technical effects and solutions improve computational efficiency by organizing connectable groups into cliques, which simplifies the process of identifying optimal configurations for power management.

In addition to one or more of the features described above or below, additional features disclose the computer operations further comprise executing a weighted set covering algorithm to find a set of the connectable groups to account for all of the intermediate local clock buffers. Technical effects and solutions utilize advanced algorithms to identify the most cost-effective set of connectable groups, ensuring comprehensive coverage of all intermediate local clock buffers and optimizing the overall power management strategy.

According to one or more embodiments, a method for optimizing an integrated circuit includes associating intermediate local clock buffers to latches, the latches being associated with clock domains. The method includes creating a graph of the intermediate local clock buffers in which the intermediate local clock buffers are vertices and the vertices are connected by edges, the edges representing the intermediate local clock buffers that can be merged. Also, the method includes clustering the intermediate local clock buffers in the graph according to cliques, the cliques supporting clock domains. Further, the method includes converting the cliques of the intermediate local clock buffers into a plurality of local clock buffers of the integrated circuit, where the plurality of local clock buffers are converted from the cliques according to a number of the clock domains supported by the plurality of local clock buffers. Technical effects and solutions include providing a structured approach to identify which intermediate local clock buffers can be combined into local clock buffers. The graph-based representation facilitates the visualization and analysis of possible configurations, enabling efficient clustering of clock buffers according to cliques that support specific clock domains. Clustering the intermediate local clock buffers into cliques optimizes the use of clock resources by ensuring that each clique corresponds to a feasible configuration of clock domains, and the organization into cliques simplifies the identification of optimal configurations for power management, reducing unnecessary power consumption by ensuring that clock buffers are used effectively. Converting the cliques into local clock buffers tailored to the number of supported clock domains ensures that the integrated circuit is optimized for power efficiency, thereby allowing for the precise allocation of clock resources, minimizing power wastage, and enhancing the overall performance of the circuit by aligning the clock buffer configuration with the specific needs of the clock domains.

According to one or more embodiments, a system for optimizing an integrated circuit includes a memory comprising computer readable instructions and a processing device for executing the computer readable instructions, the computer readable instructions controlling the processing device to perform operations. The operations include associating intermediate local clock buffers to latches, the latches being associated with clock domains. The method includes creating a graph of the intermediate local clock buffers in which the intermediate local clock buffers are vertices and the vertices are connected by edges, the edges representing the intermediate local clock buffers that can be merged. Also, the method includes clustering the intermediate local clock buffers in the graph according to cliques. Further, the method includes converting the cliques of the intermediate local clock buffers into a plurality of local clock buffers of the integrated circuit, wherein the plurality of local clock buffers are converted from the cliques according to a number of the clock domains supported by the plurality of local clock buffers. Technical effects and solutions include providing a structured approach to identify which intermediate local clock buffers can be combined into local clock buffers. The graph-based representation facilitates the visualization and analysis of possible configurations, enabling efficient clustering of clock buffers according to cliques that support specific clock domains. Clustering the intermediate local clock buffers into cliques optimizes the use of clock resources by ensuring that each clique corresponds to a feasible configuration of clock domains, and the organization into cliques simplifies the identification of optimal configurations for power management, reducing unnecessary power consumption by ensuring that clock buffers are used effectively. Converting the cliques into local clock buffers tailored to the number of supported clock domains ensures that the integrated circuit is optimized for power efficiency, thereby allowing for the precise allocation of clock resources, minimizing power wastage, and enhancing the overall performance of the circuit by aligning the clock buffer configuration with the specific needs of the clock domains.

Power consumption in integrated circuits has become an increasingly important consideration in modern electronic device design. As the demand for more powerful and energy-efficient devices continues to grow, designers face challenges in accurately modeling and analyzing power consumption, particularly in complex circuits with multiple clock domains. Traditional clock gating techniques are used to reduce power consumption by selectively disabling portions of a circuit when they are not in use. However, these techniques have limitations when applied to circuits with numerous small domains. In such cases, using standard Local Clock Buffers (LCBs) for each domain results in a large number of underloaded LCBs, potentially leading to inefficient power usage.

Leaf level clock drivers have a capability to gate off the clock signal to prevent the latches they drive from switching in order to conserve power. Small gating domains or non-localized latch distribution can cause these leaf level clock drivers to be underloaded limiting the power savings. To mitigate this effect, these leaf level drivers can be designed with more than one output with independent gating signals. Embodiments of the present disclosure provide a method of associating latches with the different types of leaf level drivers, which are local clock buffers, for the purpose of minimizing the power consumption. It is noted that leaf level clock gating cells are referred to as local clock buffers.

Leaf level clock drivers (e.g., single gated local clock buffers that may be referred to as LCBESs) traditionally have had one functional output nominally capable of driving a fixed number (n) of minimum power level latches. The single gated local clock buffer has a single functional output that can be gated and is controlled by an enable signal. Because of small clock gating domain sizes (e.g., less than n latches) and latches within a domain being spread out across a wide area, it is common for these single gated local clock buffer cells to be under loaded (e.g., driving less than n latches). Because each single gated local clock buffer represents a load on the global clock distribution and because each single gated local clock buffer consumes internal switching power with each clock transition, this results in some unnecessary power consumption compared to the situation where each single gated local clock buffer is fully loaded (e.g., drives n latches). Micro gated local clock buffers (e.g., LCBESU2s and LCBES4s) are designed to mitigate this situation. One type of micro gated local clock buffer (e.g., LCBESU2) has two independently gated functional outputs each output driving approximately half (½) the load of a single gated local clock buffer. Another type of micro gated local clock buffer (e.g., LCBESU4) has four independently gated functional outputs each output driving approximately one-fourth (¼) the load of single gated local clock buffer. It is noted that both types of micro gated local clock buffers (e.g., LCBESU2 and LCBESU4) also have a master enable that can disable all the functional outputs. Although examples may depict one, two, and four functional outputs for explanation purposes, it should be appreciated that any number of one or more functional outputs may be utilized for a micro gated local clock buffer in accordance with one or more embodiments.

One or more embodiments assign groups of latches to leaf level drivers with various number of functional outputs. The method can form a graph in which vertices represent single intermediate clock domain drivers and edges represent two drivers that can be merged. Edges are assigned costs and vertices are assigned values unique to each clock domain. K-cliques are found, and each clique is assigned a cost based upon the vertices and edges in the clique. A minimum cost weighted set cover algorithm is used to choose the cliques to be used, which provides the association of latches to gated leaf level drivers. The graph can be dynamically pruned to reduce the problem size.

Descriptions of various embodiments of the present disclosure are presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random-access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

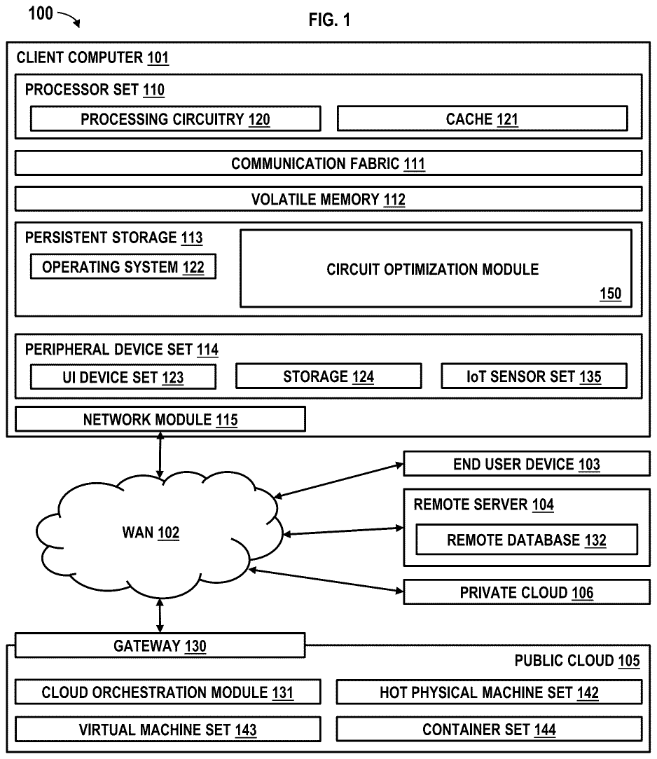

FIG. 1 illustrates a computing environment 100, according to an embodiment. Computing environment 100 contains an example of an environment for the execution of at least some of the computer code involved in performing the inventive methods, such as a circuit optimization module 150 for performing circuit design optimization for attaching latches to different types of local clock buffers according to the clock domain of the latches. In addition to the circuit optimization module 150, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and circuit optimization module 150, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in circuit optimization module 150 in persistent storage 113.

COMMUNICATION FABRIC 111 is the signal conduction path that allows the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid-state storage devices. Operating system 122 may take several forms, such as various known proprietary operating systems or open-source Portable Operating System Interface-type operating systems that employ a kernel. The code included in the circuit optimization module 150 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

According to one or more embodiments, the computing environment 100 can provide for remote data storage. For example, the computer 101 can be a cloud storage system or other suitable system for storing data that is accessible to a user remotely, such as by accessing the computer 101 using the end user device 103. That is, a user can send a user operation (also referred to as a “user request”) from the end user device 103 to the computer 101 via the WAN 102. Although the user operation may appear to be simple, such as uploading an object to a cloud storage system, the complications of operating a cloud computing system often have side effects and produce ancillary data, which may be consumed by both the operator of the system (e.g., the computer 101) and by users or other components of the cloud architecture (e.g., the computing environment 100). Ancillary data may be created by user operations that trigger the creation of the ancillary data. Ancillary data may be resource consumption information, notification data, and/or the like, including combinations and/or multiples thereof. Data for an independent event may be inferred from another event (e.g., event to update resource consumption information for an entity in a system also means that the total consumption information for the oner of the entity is also updated).

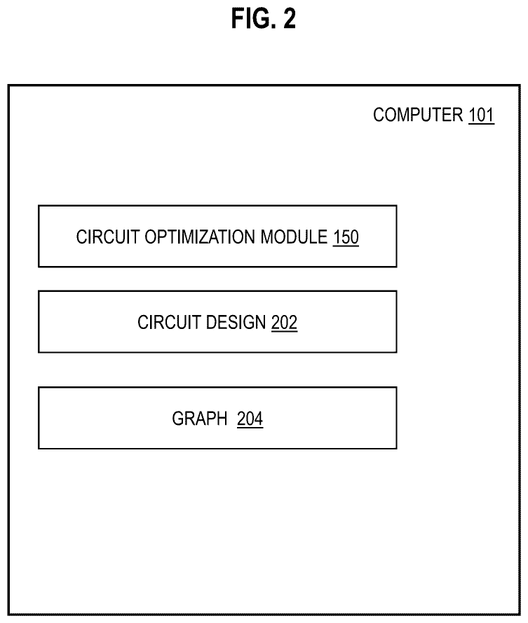

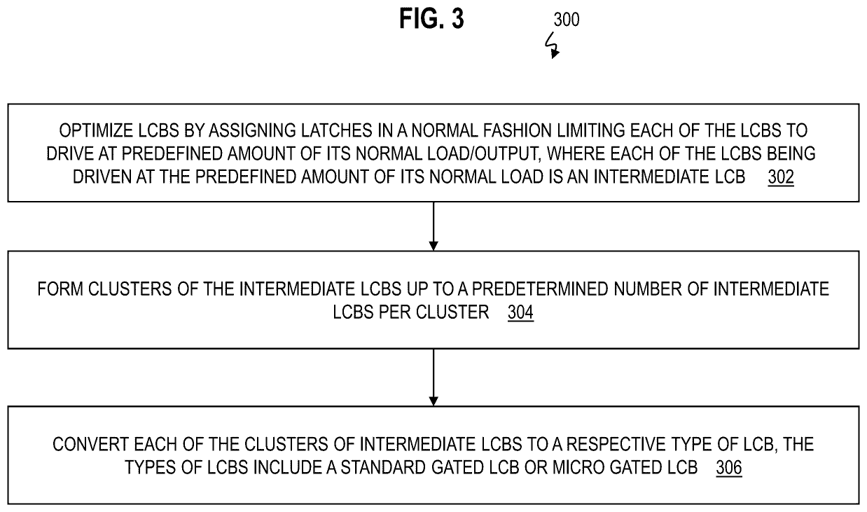

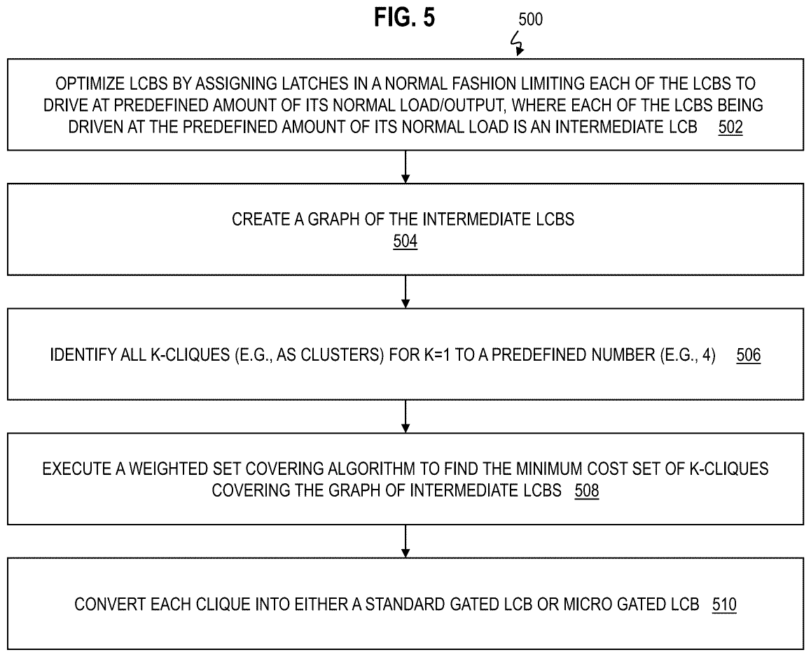

FIG. 2 depicts a block diagram of the computer 101 with further details for performing circuit design optimization by associating latches with different types of local clock buffers based on clock domains for the latches in accordance with exemplary embodiments. FIG. 3 depicts a flow diagram of a computer-implemented method 300 for performing circuit design optimization by associating latches with different types of local clock buffers based on clock domains for the latches in accordance with exemplary embodiments. In exemplary embodiments, the method 300 can be performed by the circuit optimization module 150 of the computer 101 in the computing environment 100 shown in FIG. 1. The circuit optimization module 150 may be part of an electronic design application (EDA) that is used to design and test integrated circuits, resulting in an integrated circuit design 202 for fabricating an integrated circuit. The integrated circuit can have processing circuity, logic circuits, etc., connected to the latches. For a given clock distribution signal and power domain, latches are assigned to various local clock buffers. FIG. 3 illustrates a high-level flow diagram, while FIG. 5 illustrates details in accordance with one or more exemplary embodiments.

Turning to FIG. 3, at block 302 of the computer-implemented method 300, the circuit optimization module 150 is configured to optimize local clock buffers (LCBs) by assigning latches in a typical fashion limiting each of the local clock buffers to drive at a predefined amount of its normal load/output. Each local clock buffer that is driven at the predefined amount of its normal load/output is called an intermediate local clock buffer. The predefined amount is less than the normal load/output. Typically, latches are assigned to local clock buffers based on criteria such as the physical locality of the latches (e.g., only latches close to each other would be assigned to the same clock buffer) and the maximum drive capability of the local clock buffer (which is typically some capacitive load but may be simplified to be the maximum number of minimum power level latches that it can drive). In any case, one or more embodiments are not meant to be limited to how this is done. In typical cases, locality in one form or another is used when clustering latches to local clock buffers. It is noted that latches may be utilized for explanation purposes; it should be appreciated that embodiments are not limited to latches and any type of suitable memory element may be utilized including flip-flops, registers (e.g., single bit registers and multiple bit registers), etc.

At block 304, the circuit optimization module 150 is configured to form clusters of the intermediate local clock buffers up to a predetermined number (e.g., K) of intermediate local clock buffers per cluster. These clusters refer to cliques from the graph discussed further herein.

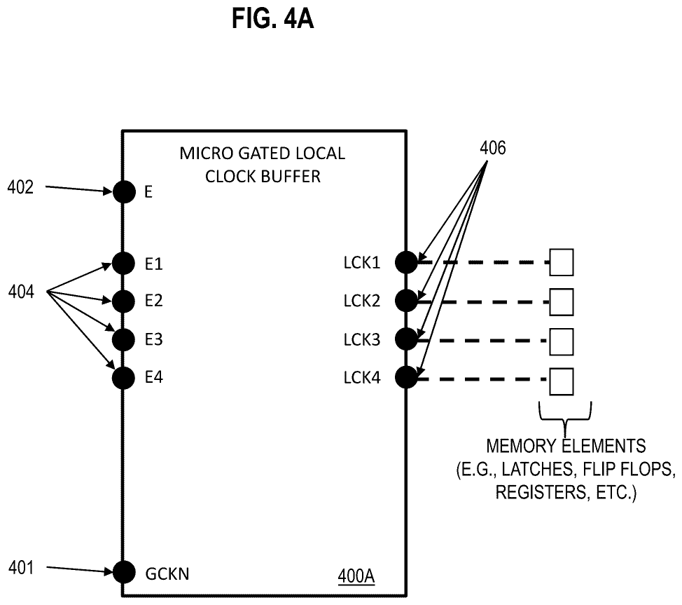

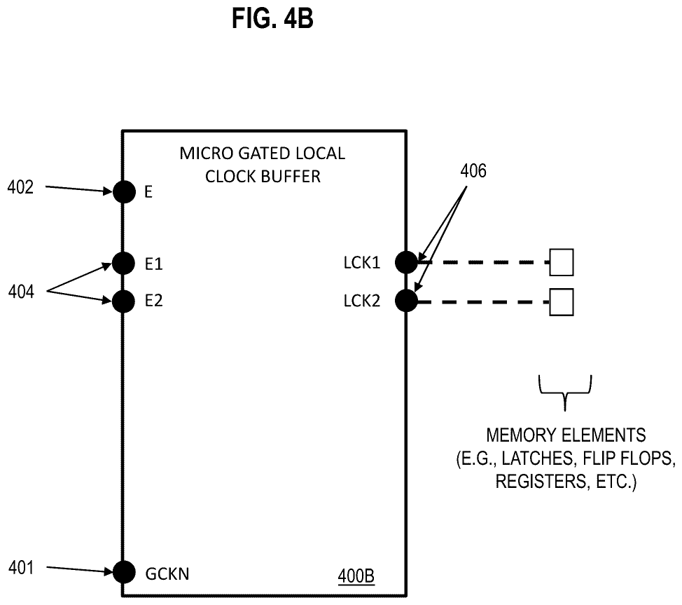

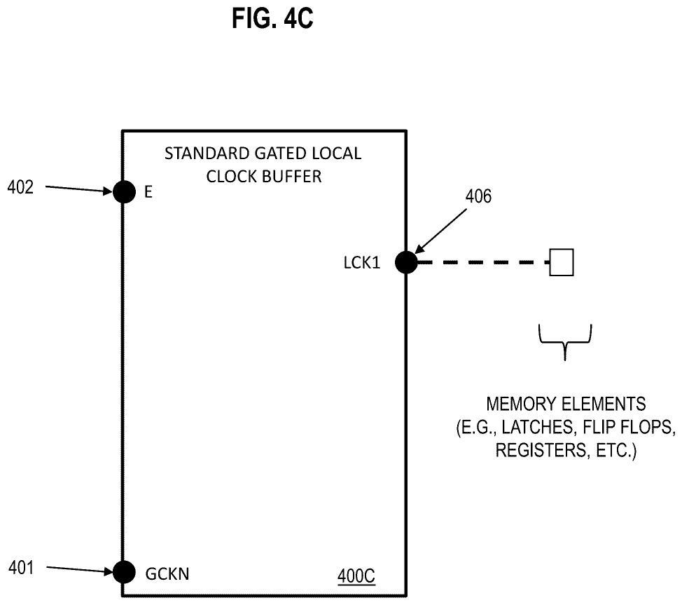

At block 306, the circuit optimization module 150 is configured to convert each of the clusters of intermediate local clock buffers to a respective type of local clock buffer. The types of local clock buffers include a standard gated local clock buffer and micro gated local clock buffers. In one or more exemplary embodiments, examples of the micro gated local clock buffers are depicted in FIGS. 4A and 4B. In one or more exemplary embodiments, an example of a standard gated local clock buffer is depicted in FIG. 4C.

In one or more embodiments, each cluster can be converted into (either) a single gated local clock buffer (e.g., depicted in FIG. 4C with a single functional output), a micro gated local clock buffer (e.g., depicted in FIG. 4B with two functional output), or a different types of micro gated local clock buffer (e.g., depicted in FIG. 4A with four functional outputs). The particular type of LCB used is determined based on the number of unique enable signals from the intermediate local clock buffers in the cluster, where the unique enable signals correspond to the number of unique clock domains represented by the intermediate local clock buffers in that cluster. For example, one unique enable signal in a cluster results in a single gated local clock buffer, e.g., depicted in FIG. 4C with a single functional output (e.g., LCBES), two unique enable signals in a cluster result in a micro gated local clock buffer, e.g., depicted in FIG. 4B with two functional outputs (e.g., LCBESU2), and three or more unique enable signals in a cluster result in a micro gated local clock buffer, e.g., depicted in FIG. 4A with four functional outputs (e.g., LCBESU4). Each cluster has one or more clock domains, and each cluster of intermediate LCBs can be implemented in some type of standard or micro gated local clock buffer, as discussed further herein.

In one or more embodiments, for the two unique enable signals case, if three intermediate LCBs belong to one clock domain and one intermediate LCB belongs to a second clock domain, then an LCBESU4 should be used. This is because each functional output of the LCBESU2 can only drive about half the load of an LCBES. In order to use an LCBESU2, there should be no more than two intermediate LCBs from the same clock domain connected to the same functional output in one or more embodiments.

Referring now to FIGS. 4A and 4B, block diagrams are depicted of micro gated local clock buffers 400A and micro gated local clock buffers 400B with global and micro enables in accordance with an exemplary embodiment. The descriptions of the micro gated local clock buffers 400A and the micro gated local clock buffers 400B are analogous except they have different numbers of micro enables inputs and different numbers of functional outputs as can been seen in FIGS. 4A and 4B.

The micro gated (clocking) local clock buffers 400A and 400B include an optional global enable input 402, micro enables input 404, functional clock outputs 406, optional scan clock outputs (not shown), and a global clock signal input 401. The micro gated local clock buffers 400A and 400B are designed to manage clock signals within a circuit. The micro gated local clock buffers 400A and 400B may receive input at the optional global enable (signal) input 402, which controls the overall enabling of the clock signals. In this case, the global enable signal would be driven by a signal that is the ORing of the mirco enable signals. The global enable signal input 402 allows the micro gated local clock buffers 400A and 400B to respectively activate or deactivate the clock signals based on the input it receives. In one or more embodiments, the optional global enable input 402 may not be utilized in FIGS. 4A and 4B.

The micro enables input 404 provides individual control over multiple clock domains within the micro gated local clock buffer 400A and 400B. Each input in the micro enables input 404 corresponds to a specific clock domain, allowing for selective enabling or disabling of these clock domains. This feature enables fine-grained control over the clock signals, optimizing power consumption by deactivating unused clock domains. The functional clock outputs 406 are the primary clock outputs of the micro gated local clock buffers 400A and 400B. These outputs deliver the clock signals to various functional units within the circuit. For example, one of the functional units may be a latch. Each output in the functional clock outputs 406 corresponds to a specific clock domain controlled by the corresponding micro enable input 404. The optional scan clock outputs may be used for testing and diagnostic purposes. These outputs provide clock signals to scan chains within the circuit, enabling the verification of the circuit's functionality and the detection of faults. The scan outputs ensure that the circuit operates correctly under various conditions.

The global clock signal input 401 is the main clock signal input to the micro gated local clock buffers 400A and 400B. The global clock signal input 401 provides the base clock signal that is distributed and managed by the micro gated local clock buffers 400A and 400B. The micro gated local clock buffers 400A and 400B use the global clock signal input 401 in conjunction with the (global enable signal to) global enable input 402 and (respective micro enable signals to) micro enables input 404 to generate the appropriate clock signals for the functional clock outputs 406.

FIG. 4C depicts a block diagram of a standard gated local clock buffer 400C in accordance with an exemplary embodiment. In one or more embodiments, the standard gated local clock buffer 400C may have the global enable input 402, a single functional clock output 406, optional scan clock outputs, and a global clock signal input 401. It is noted that the standard gated local clock buffer 400C does not include the micro enable input 404, and the global enable input 402 serves this purpose because the standard gated local clock buffer 400C has a single functional clock output 406.

FIG. 5 depicts a flow diagram of a computer-implemented method 500 for performing circuit design optimization by associating latches with different types of local clock buffers in accordance with exemplary embodiments. In exemplary embodiments, the method 300 is performed by the circuit optimization module 150 of the computer 101 in the computing environment 100 shown in FIG. 1.

At block 502 of the computer-implemented method 300, the circuit optimization module 150 is configured to optimize local clock buffers (LCBs) by assigning latches in a typical fashion limiting each of the local clock buffers to drive at a predefined amount of its normal load/output. Each local clock buffer that is driven at the predefined amount of its normal load is called an intermediate local clock buffer. It is noted that the predefined amount is determined by a divisor d. In some example scenarios, the divisor d=4, but one or more embodiments are not limited to d=4.

In one or more embodiments, latches are first assigned to local clock buffers in the typical (e.g., based on load and locality) fashion except that each local clock buffer is treated as only being able to drive one-fourth (¼) of its normal load/output. For example, ¼ is 1/d in example scenarios. These ¼ load local clock buffers may be designated as quarter local clock buffers (qLCBs), which can be referred to as intermediate local clock buffers. The quarter local clock buffers have one quarter of the drive strength of the output of a normal local clock buffer. Although intermediate local clock buffers can be used interchangeably with quarter local clock buffers, it should be appreciated that the intermediate local clock buffers can be representative of a different drive load/output than ¼ the normal load/output, which may be greater than or less than ¼ the normal load/output. The output (e.g., single functional clock output 406) of the standard gated local clock buffer 400C can represent a normal load/output.

The exact technique in which latches are assigned to quarter local clock buffers is not relevant for the disclosure. In one or more embodiments, latches can be assigned to quarter local clock buffers based on proximity (e.g., latches that are physically close to each other on the circuit), a common clock gating signal, fanout, load, etc. Any suitable approach may be used. The quarter local clock buffers can be temporarily placed in the center of the bounding box of the latches that they drive. For example, there may be latches having a distance to one another such that the latches can be encompassed within a bounding box, and the quarter local clock buffers can be placed in the center of the bounding box to drive the latches therein. In one or more embodiments, the bounding box can be determined by finding the smallest rectangle that encloses all of the latches driven by the quarter local clock buffer.

At block 504, the circuit optimization module 150 is configured to generate a graph 204 representing the intermediate local clock buffers and their ability to merge into a standard gated local clock buffer or a micro gated local clock buffer. In one or more embodiments, the graph may be created internally to the code of the circuit optimization module 150. The graph can be created in any suitable manner in accordance with one or more embodiments. In one or more embodiments, the circuit optimization module 150 may include, call, or employ a suitable graphing software tool to create the graph 204 where, for example, nodes and edges can be fed to the graphing software tool.

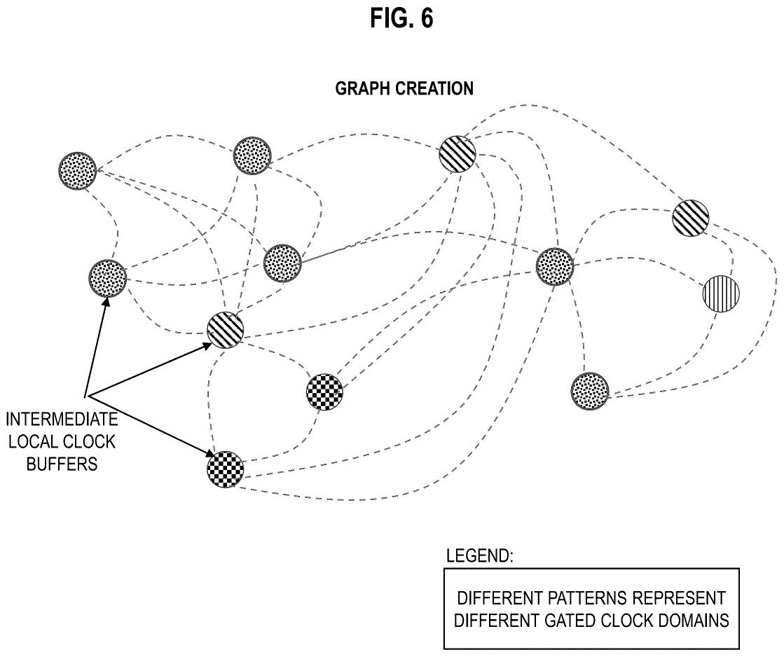

An example graph is depicted in FIG. 6. The circuit optimization module 150 graph is configured to create a graph where each intermediate local clock buffer (e.g., qLCB) is a vertex (e.g., node), and pairs of mergeable vertices are connected by an edge. An edge connecting each vertex represents the ability for two intermediate local clock buffers (e.g., qLCBs) to be implemented in the same local clock buffer.

Each vertex can have an attribute (e.g., an integer) associating the vertex with an enable signal. The attribute of the vertex can represent the clock domain, such that vertices having the same clock domain (e.g., same unique enable signal) have the same integer. Each edge can have a cost associated with it. One possible cost function represents the distance between the intermediate local clock buffers on either of its vertices. It is possible that all vertices could have edges between them, but in practice most edges are to be pruned out because 1) the latches driven by the intermediate local clock buffers would be too far from each other to practically be driven by the same LCB and/or 2) to reduce the problem size. Therefore, edges can be weighted based on the distance between connecting intermediate local clock buffers. The edges can be pruned dynamically during graph creations or afterward.

As can be seen, edges represent absolute constraints such as the logical ability to merge. If vertices are too far apart on an integrated circuit, they cannot be merged. Additional constraints can limit the number of edges such as: minimization of latch movement, problem size reduction (e.g., an edge may not be connected because that edge causes the nondeterministic polynomial (NP) problem to be larger), and the farther the distance between vertices the higher cost (e.g., in terms of timing, etc.). In FIG. 6, different patterns represent different gate clock domains. As noted herein, each clock domain represents a unique enable signal. Since there are four different clock domains according to the number of patterns depicted in FIG. 6, there are four unique enable signals.

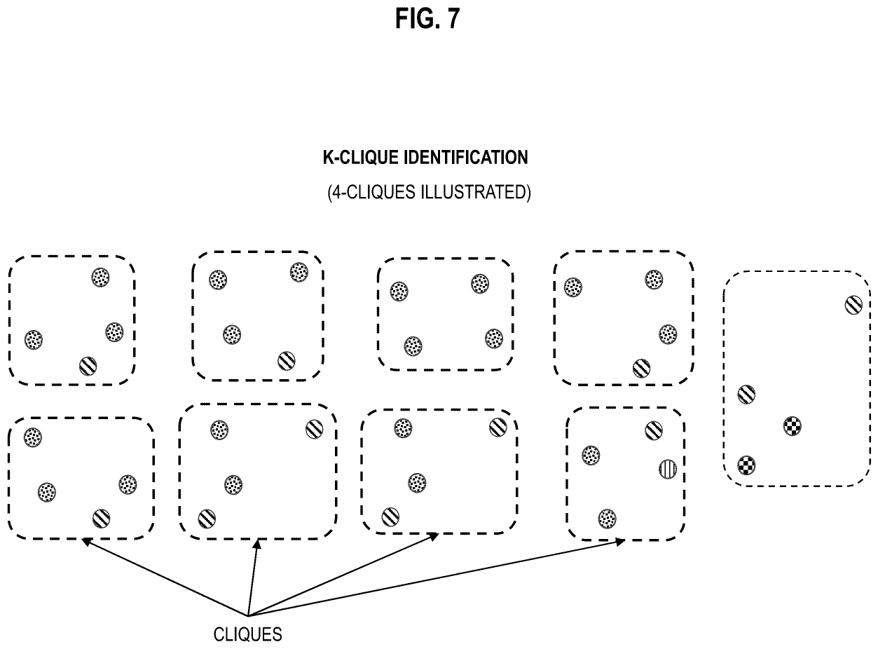

Turning back to FIG. 5, at block 506, the circuit optimization module 150 is configured to identify all K-cliques (e.g., clusters) for K=1 up to a predefined number (e.g., 4). For example, K=1, 2, 3, and 4, and when K<4, this means that an LCB is not fully loaded or that not all functional outputs are utilized. It is more efficient (e.g., in terms of circuit real estate on a chip and power) to have four intermediate local clock buffers per clique or as close as possible to four intermediate local clock buffers in each clique, when K=1-4. FIG. 7 depicts an example of the identification of all K-cliques (for K=1, 2, 3, 4), for fully connected subgraphs. Particularly, FIG. 7 illustrates all the 4-clique options for the graph 204 illustrated in FIG. 6. Options with less than four intermediate local clock buffers are not shown because they would be inefficient in circuit optimization with micro gated local clock buffers.

Each clique is assigned a cost that is a function of: 1) the type of LCB; and 2) the weight of the edges between the vertices in the clique. Each clique represents a possible micro gated local clock buffer (e.g., micro gated local clock buffers 400A and 400B) or standard gated local clock buffer (e.g., standard gated local clock buffer 400C). The identification of cliques can be performed in at most O(n^{k}k²) time. Due to pruning the graph, the identification of cliques is significantly faster, for example, closer to O(n²).

As noted herein, each clique can be assigned a cost. In one or more embodiments, each micro gated local clock buffer (e.g., where the clique has different enables on its intermediate local clock buffers (e.g., qLCBs)) has a base cost W_{mcg}. W_{mcg} is the cost of a micro gated local clock buffer, and that cost is independent of how many functional outputs are used. Standard gated local clock buffers have a base cost of W_{std}. In one or more embodiments, the cost of a standard gated local clock buffer is less than the cost of a micro gated local clock buffer, for example, W_{std}<W_{mcg}.

Each clique can have an additional cost that may include, for example, the distance between latches. Additional costs should total to less than (<) W_{mcg}, which means that W_{clique}<W_{std}+W_{mcg}, where W_{clique} is the cost of the clique.

Now that the K-cliques have been identified for the intermediate local buffers (e.g., qLCBs), discussion turns to how to select the cliques (e.g., clusters) that cover/include all the intermediate local clock buffers in the graph 204. At block 508, the circuit optimization module 150 is configured to execute a (minimum cost) weighted set covering algorithm to find the minimum cost set of K-cliques (e.g., for LCBs) covering the intermediate local clock buffers. Because it is possible to have more than one clique cover the same vertex, that vertex is removed from all but one of those cliques.

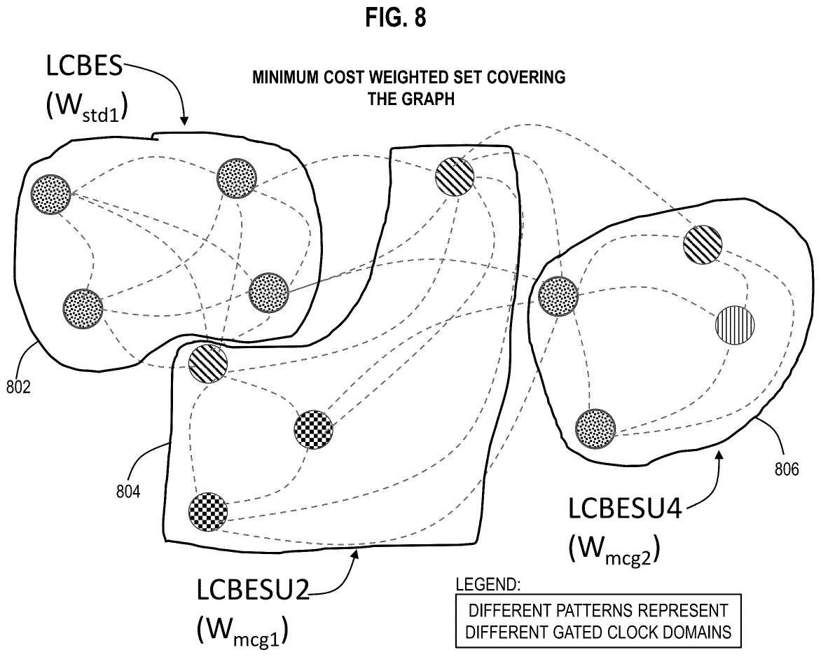

The objective is to find the minimum set of K-cliques that includes all the nodes, which are intermediate local clock buffers, in the example graph in FIG. 6. The problem to be solved is a nondeterministic polynomial (NP) complete problem, which can be solved with heuristics, and the goal is to find the lowest cost set of cliques that include (cover) all the vertices in the graph. The problem is NP-complete because it may require evaluating numerous combinations to find the optimal solution, which can be computationally intensive as the size of the graph increases. As depicted in FIG. 8, the minimum cost weighted set that covers the graph of intermediate local clock buffers in FIG. 6 includes three different cliques each with four intermediate local clock buffers. FIG. 8 illustrates clique 802, clique 804, and clique 806 as a set of cliques that fully cover the graph, where each is a 4-clique having four vertices or intermediate local clock buffers therein. The set of cliques 802, 804, and 806 determines which intermediate local clock buffers (e.g., qLCBs) are combined to form LCBs and determines the type of LCB for each clique.

Examples of weighted set covering algorithms may include the following. 1) Greedy Algorithm: This is a heuristic approach that iteratively selects the subset that covers the largest number of uncovered elements, weighted by cost, until all elements are covered. 2) Linear Programming Relaxation: This method involves relaxing the integer constraints of the set covering problem to allow fractional values, solving the resulting linear program, and then rounding the solution to obtain an integer solution. 3) Branch and Bound: This is an exact algorithm that systematically explores the solution space by branching on decisions and using bounds to prune suboptimal solutions, aiming to find the minimum cost cover. 4) Genetic Algorithms: These are evolutionary algorithms that use operations such as selection, crossover, and mutation to evolve a population of solutions towards an optimal set cover. 5) Simulated Annealing: This probabilistic technique explores the solution space by allowing occasional uphill moves to escape local minima, gradually reducing the probability of such moves to converge on an optimal solution.

It should be appreciated that any suitable weighted set covering algorithm may be utilized, and these algorithms may vary in complexity and efficiency.

The weighted set cover problem is often represented as a matrix where the rows represent the qLCBs (e.g., vertices in the graph) that need to be covered. Previous steps would have identified all of the cliques in the graph with a clique size K=1 to K=4. If there were micro gated local clock buffers with more than four outputs, K would be larger. The columns in the matrix represent these cliques. Going down each column, there is an entry made for each row that the column covers (e.g., each qLCB making up the clique). A set cover represents a set of columns that have an entry for every row. Each column (e.g., clique) is assigned a cost. The cost function used to determine the cost can vary but, in the example case, one or more embodiments of the present disclosure used the formula: LCB_Cost*distVsLCBTypeFrac+(1.0−distVsLCBTypeFrac)*(avg distance between vertices in the clique/distance limit) where:

LCB Cost is 0.7 for a standard LCB and 1.0 for a micro clock gated LCB. The distVsLCBTypeFrace is a fraction between 0 and 1 that determines which is more important: LCB type or distance. An example set cover algorithm used in one or more embodiments is from the following paper: “An effective and simple heuristic for the set covering problem,” by Guanghui Lan, Gail W. DePuy, and Gary E. Whitehouse from The European Journal of Operational Research, 2007.

Turning back to FIG. 5, at block 510, the circuit optimization module 150 is configured to convert each clique into a local clock buffer such as, for example, a standard gated local clock buffer or a micro gated local clock buffer. Because each clique can be a K-clique where K=1, 2, 3, 4, each clique may have 1, 2, 3, or 4 different clock domains (e.g., up to K clock domains). A clock domain corresponds to unique enable signal. Accordingly, four different clock domains correspond to four unique enable signals.

If a clique has intermediate local clock buffers each with the same clock domain, the circuit optimization module 150 converts this clique to a standard gated local clock buffer. For example, in FIG. 8, clique 802 is converted to a standard gated local clock buffer, and the clique 802 includes intermediate local clock buffers each with the same clock domain as denoted by the each of the vertices having the same pattern (e.g., a dotted pattern). FIG. 8 shows the LCBES representing a standard gated local clock buffer.

If a clique has intermediate local clock buffers with two or more clock domains, the circuit optimization module 150 converts this clique to a micro gated local clock buffer. For example, in FIG. 8, clique 804 is converted to a micro gated local clock buffer, and the clique 804 includes intermediate local clock buffers with two different clock domains as denoted by the vertices having the two different patterns (e.g., a diagonal pattern and checkered pattern). FIG. 8 shows the LCB as LCBESU2, which is a micro gated local clock buffer that has two functional outputs to match the two different clock domains in clique 804.

If a clique has intermediate local clock buffers with three or more clock domains, the circuit optimization module 150 converts this clique to a micro gated local clock buffer. For example, in FIG. 8, clique 806 is converted to a micro gated local clock buffer, and the clique 806 includes intermediate local clock buffers with three different clock domains as denoted by the vertices having the three different patterns (e.g., a diagonal pattern, a checkered pattern, and a vertical pattern). FIG. 8 shows the LCB as LCBESU4, which is a micro gated local clock buffer that has four functional outputs to accommodate the three different clock domains in clique 806. It is noted that the LCBESU4 could accommodate four different clock domains because the LCBESU4 has four functional outputs, although clique 806 is illustrated with three different clock domains for explanation purposes.

Further, it is noted that because it is possible to have more than one clique cover the same vertex, that vertex is removed from all but one of those cliques. Because of the nature of a minimum cost set, covering the number of cases where a vertex belongs to multiple chosen cliques should be naturally limited.

Turning to further details regarding graph pruning, as discussed herein, the graph 204 can be pruned dynamically during graph creation or after graph creation. There are various constraints that may be considered. If there are many logically mergeable intermediate local clock buffers (e.g., qLCBs), it should be recognized that the intermediate local clock buffers (e.g., qLCBs) are to distributed across a large area and limiting the distance between connected intermediate local clock buffers (e.g., qLCBs) should have limited effect on the quality of record (QOR) but should significantly reduce runtime for K-clique identification and the weighted set covering problem.

According one or more embodiments, the circuit optimization module 150 can perform graph pruning dynamically by adjusting the region size which includes:
1) Putting all the intermediate local clock buffers (e.g., qLCBs) in a k-dimensional tree (kd-tree) (with O(n log n) to create the kd-tree), where “n” is the number of vertices (e.g., intermediate local clock buffers).
2) Selecting min and max numbers of edges allowed to be incident on a vertex (e.g., Eₘᵢₙ and Eₘₐₓ), where Eₘᵢₙ is the minimum number of edges and Eₘₐₓ is the maximum number of edges.
3) Using the average intermediate local clock buffer density to find an initial radius (r) of a region containing Eₘₐₓ intermediate local clock buffers.
4) For each intermediate local clock buffer (e.g., qLCB): a) Use the kd-tree to find all the intermediate local clock buffers within radius r of the intermediate local clock buffers where O(sqrt(n)+p) and where p=points in region; b) If the intermediate local clock buffer count is >Eₘₐₓ, then radius r may be reduced for this intermediate local clock buffer; and c) If the number of intermediate local clock buffers within radius r is <Eₘᵢₙ, then r may be increased for this intermediate local clock buffer. It is noted that the intermediate clock buffer count is the number of qLCBs found within the radius r of the current qLCB being processed or looked at.

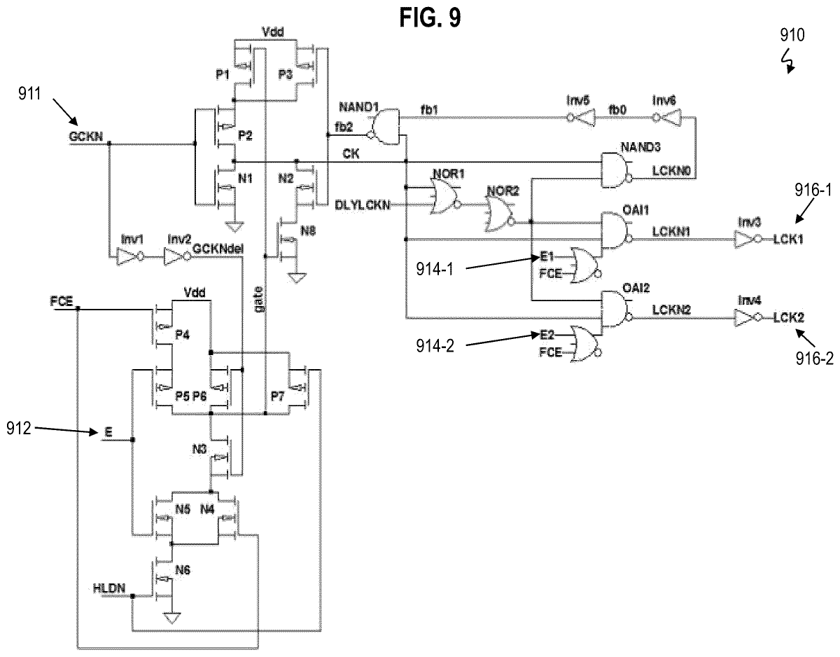

Referring now to FIG. 9, an example schematic of a micro-domain clock gating circuit 910 with multiple enable signals and corresponding output clocks in accordance with an exemplary embodiment is shown. Although this example illustrates a circuit of a micro gated local clock buffer with two micro enable inputs and two functional outputs, it should be appreciated that micro gated local clock buffers can have more than two micro enable inputs and two functional outputs.

In FIG. 9, the circuit 910 includes a global clock signal 911, a global enable signal 912, a first micro enable signal 914-1, a second micro enable signal 914-2, a first clock output signal 916-1, and a second clock output signal 916-2. The global clock signal 911 provides the base clock signal for the circuit 910. The global clock signal 911 is distributed and managed within the circuit 910 to generate the appropriate clock signals for various components. The global enable signal 912 controls the overall enabling of the clock signals within the circuit 910. The global enable signal 912 allows the circuit 910 to activate or deactivate the clock signals based on the input it receives.

The first micro enable signal 914-1 provides individual control over a specific clock domain within the circuit 910. The first micro enable signal 914-1 allows for selective enabling or disabling of this domain, optimizing power consumption by deactivating unused domains. The second micro enable signal 914-2 provides individual control over another specific clock domain within the circuit 910. The second micro enable signal 914-2 allows for selective enabling or disabling of this domain, further optimizing power consumption by deactivating unused domains. The first clock output signal 916-1 is the primary clock output for the clock domain controlled by the first micro enable signal 914-1. The first clock output signal 916-1 delivers the clock signal to various functional units within the circuit 910. The second clock output signal 916-2 is the primary clock output for the clock domain controlled by the second micro enable signal 914-2. The second clock output signal 916-2 delivers the clock signal to various functional units within the circuit 910.

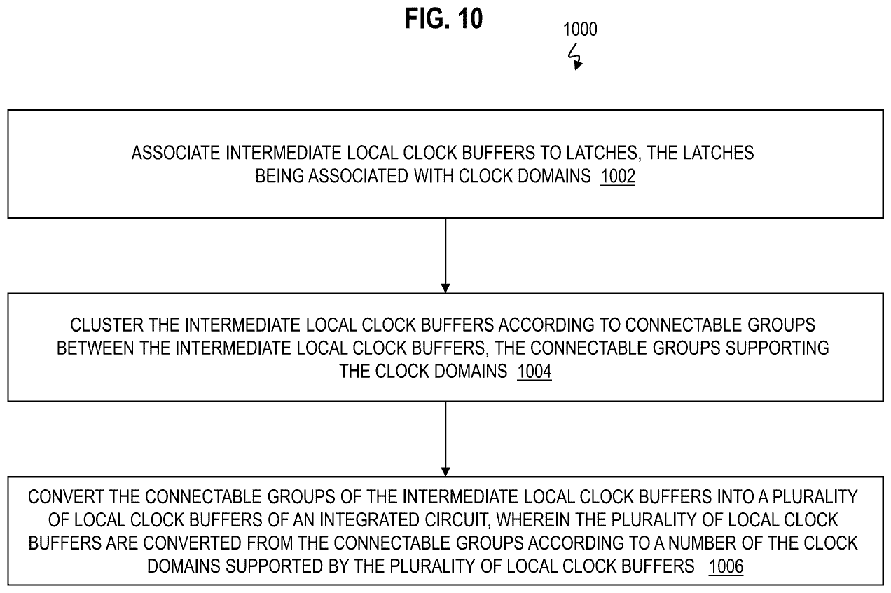

FIG. 10 depicts a flowchart of a computer-implemented method 1000 of performing circuit design optimization for attaching latches to different types of local clock buffers according to the clock domain of the latches in order to form an integrated circuit design 202. Reference can be made to any figures discussed herein.

At block 1002 of computer-implemented method 1000, the circuit optimization module 150 is configured to associate intermediate local clock buffers to latches, the latches being associated with clock domains. An example is depicted in FIG. 6 according to one or more embodiments. In one or more embodiments, an intermediate local clock buffer can be representative of a quarter local clock buffer (qLCB). At block 1004, the circuit optimization module 150 is configured to cluster the intermediate local clock buffers according to connectable groups between the intermediate local clock buffers, the connectable groups supporting the clock domains. An example is depicted in FIG. 7 according to one or more embodiments. At block 1006, the circuit optimization module 150 is configured to convert the connectable groups of the intermediate local clock buffers into a plurality of local clock buffers of an integrated circuit, where the plurality of local clock buffers are converted from the connectable groups according to a number of the clock domains supported by the plurality of local clock buffers. An example is depicted in FIGS. 7 and 8 according to one or more embodiments.

The intermediate local clock buffers include a predefined portion of drive power of the plurality of local clock buffers. In one or more embodiments, the predefined portion can be ¼ the normal load on a functional output of a standard gated local clock buffer. A connectable group in the connectable groups includes the intermediate local clock buffers that are convertible to a local clock buffer. In one or more embodiments, a connectable group is a cluster or clique. A clique in a graph is considered to be a collection of vertices where each vertex in the clique is connected to every other vertex in the clique by an edge.

The connectable groups are cliques in which each clique includes up to a predefined number of the intermediate local clock buffers. In one or more embodiments, each clique can include up to K intermediate local clock buffers.

The circuit optimization module 150 is configured to execute a weighted set covering algorithm to find a set of the connectable groups to account for all of the intermediate local clock buffers. Each connectable group in the set of the connectable groups is converted to one of the plurality of local clock buffers. Examples of local clock buffers may include micro gated local clock buffer 400A, micro gated local clock buffer 400B, a standard gated local clock buffer 400C, etc.

A first type of the plurality of local clock buffers supports a first number of the clock domains. For example, the first type of local clock buffers may include micro gated local clock buffers (e.g., micro gated local clock buffer 400A) that have three or more micro enables inputs 404 and three or more functional clock outputs 406.

A second type of the plurality of local clock buffers supports a second number of the clock domains, the second number being less than the first number. For example, the second type of local clock buffers may include micro gated local clock buffers (e.g., micro gated local clock buffer 400B) that have more than one micro enable input 404 and more than one functional clock output 406.

A second type of the plurality of local clock buffers supports a second number of the clock domains, the second number being less than the first number; and a third type of the plurality of local clock buffers supports a third number of the clock domains, the third number being less than the second number. For example, the third type of local clock buffers may include standard gated local clock buffers (e.g., standard gated local clock buffer 400C) that has one micro enables input 404 and one functional clock output 406.

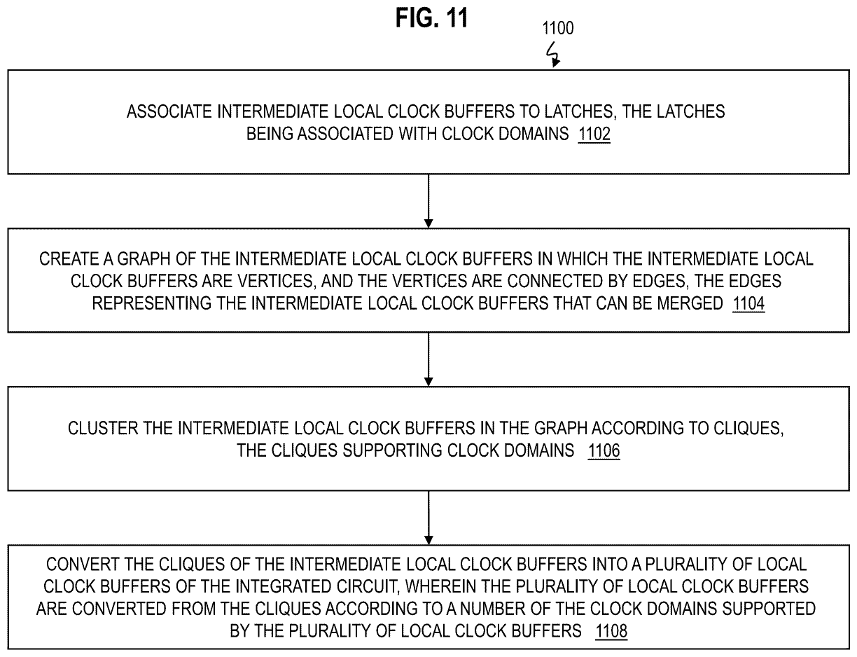

FIG. 11 depicts a flowchart of a computer-implemented method 1100 of performing circuit design optimization for attaching latches to different types of local clock buffers according to the clock domain of the latches in order to form an integrated circuit design 202. Reference can be made to any figures discussed herein.

At block 1102 of computer-implemented method 1100, the circuit optimization module 150 is configured to associate intermediate local clock buffers to latches, the latches being associated with clock domains. At block 1104, the circuit optimization module 150 is configured to create a graph 204 of the intermediate local clock buffers in which the intermediate local clock buffers are vertices (e.g., nodes) and the vertices are connected by edges, the edges representing the intermediate local clock buffers that can be merged. An example graph 204 is depicted in FIG. 6 according to one or more embodiments. At block 1106, the circuit optimization module 150 is configured to cluster the intermediate local clock buffers in the graph according to cliques, the cliques supporting clock domains. FIG. 7 depicts example cliques from which to select according to one or more embodiments. At block 1108, the circuit optimization module 150 is configured to convert the cliques of the intermediate local clock buffers into a plurality of local clock buffers of the integrated circuit, where the plurality of local clock buffers are converted from the cliques according to a number of the clock domains supported by the plurality of local clock buffers. FIG. 8 depicts an example according to one or more embodiments.

This present disclosure improves the functioning of a computer by providing a more efficient and accurate method for optimizing a circuit design by associating latches with different types of local clock buffers to more efficiently and effectively implement multi-domain clock gating circuits, specifically micro gated local clock buffers. This circuit design optimization of different types of micro gate local clock buffers in an integrated circuit along with the use of standard gated local clock buffers allows for efficient connections (e.g., functional outputs) to latches of different clock domains such that certain clock domains can be powered off while others are powered on, thereby significantly reducing power consumption of the integrated circuit according to the optimization of the different types of micro gated local clock buffers and the standard gated local clock buffer. This targeted approach can reduce the overall clock power.

For circuits with numerous small domains, the present disclosure reduces the number of standard local clock buffers, which would otherwise result in a large number of underloaded standard local clock buffers. This could lead to inefficient power usage, as the power savings from clock gating were not fully realized due to the overhead of managing multiple local clock buffers. The present disclosure optimizes the use of different types of micro gated local clock buffers in an integrated circuit, thereby reducing the total number of local clock buffers used. Accordingly, the present disclosure better captures the power savings from clock gating in multi-domain circuits. By optimizing multi-domain clock gating circuits, designers can reduce power consumption, extend battery life in portable devices, and improve overall system performance. This leads to electronic devices that are not only more energy-efficient but also more reliable and capable of handling complex tasks with reduced thermal and power-related issues.

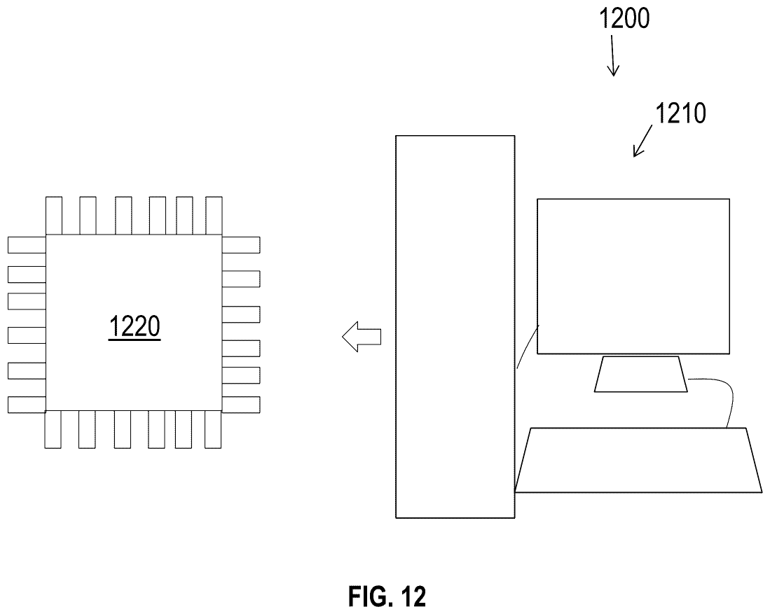

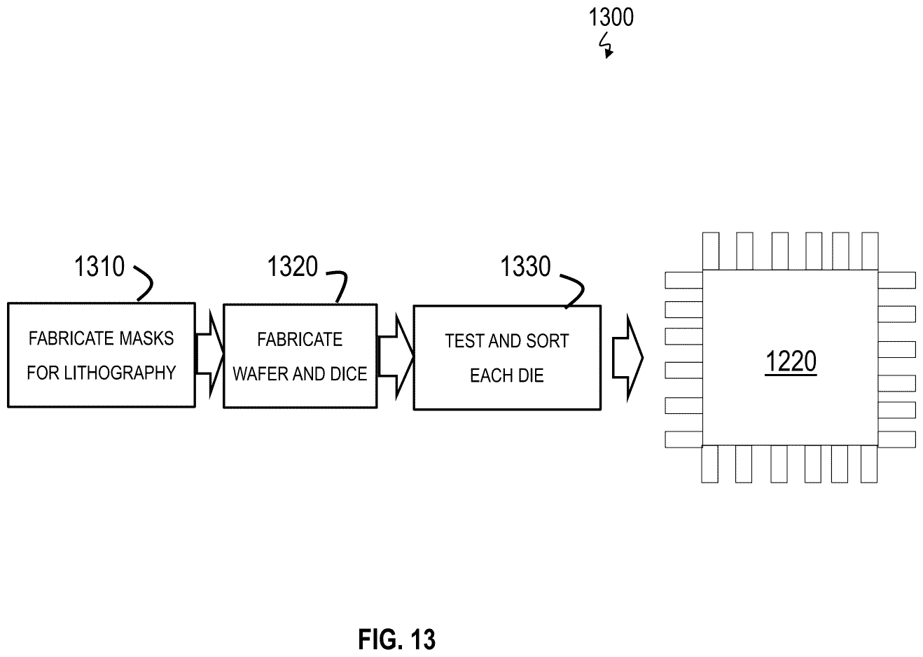

Referring now to FIG. 12, a block diagram of a system 1200 to perform circuit design optimization according to one or more embodiments. The system 1200 includes processing circuitry 1210 used to generate the circuit design 202 that is ultimately fabricated into an integrated circuit 1220. The steps involved in the fabrication of the integrated circuit 1220 are well-known and briefly described herein. Once the physical layout is finalized, based, in part, on the circuit design optimization according to one or more embodiments, the finalized physical layout is provided to a foundry. Masks are generated for each layer of the integrated circuit based on the finalized physical layout. Then, the wafer is processed in the sequence of the mask order. The processing includes photolithography and etch. This is further discussed with reference to FIG. 13.

Particularly, FIG. 13 is a flow diagram of a method 1300 of fabricating an integrated circuit according to one or more embodiments. Once the physical design data is obtained, based, in part, on performing circuit design optimization as described herein, the integrated circuit 1220 can be fabricated according to known processes that are generally described with reference to FIG. 13. Generally, a wafer with multiple copies of the final design is fabricated and cut (i.e., diced) such that each die is one copy of the integrated circuit 1220. At block 1310, the processes include fabricating masks for lithography based on the finalized physical layout. At block 1320, fabricating the wafer includes using the masks to perform photolithography and etching. Once the wafer is diced, testing and sorting each die is performed, at block 1330, to filter out any faulty die.

While the foregoing is directed to embodiments of the present disclosure, other and further embodiments of the present disclosure may be devised without departing from the basic scope thereof, and the scope thereof is determined by the claims that follow.

What is claimed is:

1. A computer-implemented method comprising:
associating intermediate local clock buffers to latches, the latches being associated with clock domains;
clustering the intermediate local clock buffers according to connectable groups between the intermediate local clock buffers, the connectable groups supporting the clock domains; and
converting the connectable groups of the intermediate local clock buffers into a plurality of local clock buffers of an integrated circuit, wherein the plurality of local clock buffers are converted from the connectable groups according to a number of the clock domains supported by the plurality of local clock buffers.

2. The computer-implemented method of claim 1, wherein the intermediate local clock buffers comprise a predefined portion of drive power of the plurality of local clock buffers.

3. The computer-implemented method of claim 1, wherein a connectable group in the connectable groups includes the intermediate local clock buffers that are convertible to a local clock buffer.

4. The computer-implemented method of claim 1, wherein the connectable groups are cliques in which each clique includes up to a predefined number of the intermediate local clock buffers.

5. The computer-implemented method of claim 1, further comprising executing a weighted set covering algorithm to find a set of the connectable groups to account for all of the intermediate local clock buffers.

6. The computer-implemented method of claim 5, wherein each connectable group in the set of the connectable groups is converted to one of the plurality of local clock buffers.

7. The computer-implemented method of claim 1, wherein a first type of the plurality of local clock buffers supports a first number of the clock domains.

8. The computer-implemented method of claim 7, wherein a second type of the plurality of local clock buffers supports a second number of the clock domains, the second number being less than the first number.

9. The computer-implemented method of claim 7, wherein:
a second type of the plurality of local clock buffers supports a second number of the clock domains, the second number being less than the first number; and
a third type of the plurality of local clock buffers supports a third number of the clock domains, the third number being less than the second number.

10. A system comprising:
a memory comprising computer readable instructions; and
a processing device for executing the computer readable instructions, the computer readable instructions controlling the processing device to perform operations comprising:
associating intermediate local clock buffers to latches, the latches being associated with clock domains;
clustering the intermediate local clock buffers according to connectable groups between the intermediate local clock buffers, the connectable groups supporting the clock domains; and
converting the connectable groups of the intermediate local clock buffers into a plurality of local clock buffers of an integrated circuit, wherein the plurality of local clock buffers are converted from the connectable groups according to a number of the clock domains supported by the plurality of local clock buffers.

11. The system of claim 10, wherein the intermediate local clock buffers comprise a predefined portion of drive power of the plurality of local clock buffers.

12. The system of claim 10, wherein a connectable group in the connectable groups includes the intermediate local clock buffers that are convertible to a local clock buffer.

13. The system of claim 10, wherein the connectable groups are cliques in which each clique includes up to a predefined number of the intermediate local clock buffers.

14. The system of claim 10, wherein the operations further comprise executing a weighted set covering algorithm to find a set of the connectable groups to account for all of the intermediate local clock buffers.

15. The system of claim 14, wherein each connectable group in the set of the connectable groups is converted to one of the plurality of local clock buffers.

16. The system of claim 10, wherein a first type of the plurality of local clock buffers supports a first number of the clock domains.

17. The system of claim 16, wherein a second type of the plurality of local clock buffers supports a second number of the clock domains, the second number being less than the first number.

18. The system of claim 16, wherein:
a second type of the plurality of local clock buffers supports a second number of the clock domains, the second number being less than the first number; and
a third type of the plurality of local clock buffers supports a third number of the clock domains, the third number being less than the second number.

19. A computer program product comprising:
a set of one or more computer-readable storage media;
program instructions, collectively stored in the set of one or more storage media, for causing a processor set to perform computer operations:
associating intermediate local clock buffers to latches, the latches being associated with clock domains;
clustering the intermediate local clock buffers according to connectable groups between the intermediate local clock buffers, the connectable groups supporting the clock domains; and
converting the connectable groups of the intermediate local clock buffers into a plurality of local clock buffers of an integrated circuit, wherein the plurality of local clock buffers are converted from the connectable groups according to a number of the clock domains supported by the plurality of local clock buffers.

20. The computer program product of claim 19, wherein the intermediate local clock buffers comprise a predefined portion of drive power of the plurality of local clock buffers.

21. The computer program product of claim 19, wherein a connectable group in the connectable groups includes the intermediate local clock buffers that are convertible to a local clock buffer.

22. The computer program product of claim 19, wherein the connectable groups are cliques in which each clique includes up to a predefined number of the intermediate local clock buffers.

23. The computer program product of claim 19, wherein the computer operations further comprise executing a weighted set covering algorithm to find a set of the connectable groups to account for all of the intermediate local clock buffers.

24. A method for optimizing an integrated circuit, the method comprising:
associating intermediate local clock buffers to latches, the latches being associated with clock domains;
creating a graph of the intermediate local clock buffers in which the intermediate local clock buffers are vertices and the vertices are connected by edges, the edges representing the intermediate local clock buffers that are mergeable;
finding cliques in the graph, the cliques comprising the intermediate local clock buffers, the cliques supporting clock domains; and
converting the cliques of the intermediate local clock buffers into a plurality of local clock buffers of the integrated circuit, wherein the plurality of local clock buffers are converted from the cliques according to a number of the clock domains supported by the plurality of local clock buffers.

25. A system for optimizing an integrated circuit, the system comprising:
a memory comprising computer readable instructions; and
a processing device for executing the computer readable instructions, the computer readable instructions controlling the processing device to perform operations comprising:
associating intermediate local clock buffers to latches, the latches being associated with clock domains;
creating a graph of the intermediate local clock buffers in which the intermediate local clock buffers are vertices and the vertices are connected by edges, the edges representing the intermediate local clock buffers that are mergeable;
finding cliques in the graph, the cliques comprising the intermediate local clock buffers, the cliques supporting clock domains; and
converting the cliques of the intermediate local clock buffers into a plurality of local clock buffers of the integrated circuit, wherein the plurality of local clock buffers are converted from the cliques according to a number of the clock domains supported by the plurality of local clock buffers.
